(19) United States
(12) Patent Application Publication
(10) Pub. No.: US 2022/0199611 A1
(43) Pub. Date: Jun. 23, 2022

(54) INSULATED-GATE BIPOLAR TRANSISTOR WITH INTEGRATED SCHOTTKY BARRIER

(71) Applicant: TEXAS INSTRUMENTS INCORPORATED, Dallas, TX (US)

(72) Inventors: Zaichen CHEN, Dallas, TX (US); Akram Ali SALMAN, Plano, TX (US); Henry Litzmann EDWARDS, Garland, TX (US)

(21) Appl. No.: 17/129,495

(22) Filed: Dec. 21, 2020

(51) Int. Cl. H01L 27/02; H01L 29/06; H01L 21/8249

(52) U.S. Cl. CPC H01L 27/0262; H01L 21/8249; H01L 29/0619

(57) ABSTRACT

In an example, an electronic device includes a first well having a first conductivity type within a semiconductor substrate and a second well having a second opposite conductivity type within the semiconductor substrate and touching the first well. The device further includes a third well having the first conductivity type within the second well. A metallic structure in direct contact with at least a portion of a surface of the third well thereby forms a Schottky barrier between the third well and the metallic structure.

### BACKGROUND

Modern day electronics extensively use sub-micron scale semiconductor integrated circuits (ICs). An IC includes an input/output (I/O) interface that enables it to interact with other electronic circuits (e.g., other ICs). Unfortunately, the I/O interface may expose the IC to electrostatic discharge events (ESDs) which may cause a sudden flow of high current into the IC. To protect the IC, an ESD protection circuit may be coupled to the I/O interface to provide a current path to ground to thereby avoid damaging components within the IC.

### SUMMARY

In an example, an electronic device includes a first well having a first conductivity type within a semiconductor substrate and a second well having a second opposite conductivity type within the semiconductor substrate and touching the first well. The device further includes a third well having the first conductivity type within the second well. A metallic structure in direct contact with at least a portion of a surface of the third well thereby forms a Schottky barrier between the third well and the metallic structure.

### BRIEF DESCRIPTION OF THE DRAWINGS

For a detailed description of various examples, reference will now be made to the accompanying drawings in which:

FIG. 1 shows an example of an integrated circuit including an ESD protection circuit coupled to an electronic device according to the disclosure.

FIG. 2 depicts an illustrative equivalent circuit diagram of an electronic device according to the disclosure.

FIG. 3 depicts a side-view cross section of an illustrative electronic device of the disclosure, in accordance with various examples.

FIG. 4 depicts an illustrative method to fabricate an electronic device of the disclosure, in accordance with various examples.

FIGS. 5-10 depict an illustrative process to fabricate an electronic device of the disclosure, in accordance with various examples.

FIG. 11 shows an example implementation of an ESD detection circuit of the disclosure.

FIG. 12 illustrates safe operating area (SOA) of an IGBT having a conventional source dopant concentration and an electronic device in which the source dopant concentration is reduced thus forming a Schottky barrier between the source and an overlying silicide layer

### DETAILED DESCRIPTION

An electrostatic discharge (ESD) event is a sudden flow of high current between two electrically charged objects due to the presence of a potential difference between the two objects. For example, a user (e.g., a human) may cause an ESD event in an electronic device by coming into electrical contact with the electronic device. This event is typically modeled by the human body model (HBM). In some cases, a charged device model (CDM) may be employed to characterize the susceptibility of an electronic device to experiencing damage from an ESD event. Any of various techniques can be used to strengthen the protection system of an IC against an ESD event. One such technique involves using an electronic element (such as a diode) at the I/O interface. When an ESD event occurs, the diode junction breaks down in sub-nanosecond response time and shunts the ESD current away from the IC, thus protecting the IC from the ESD event.

ESD protection circuits are typically configured to switch off during normal signal operation and switch on during an ESD event. An ESD protection circuit (or ESD clamp circuit) can be built to respond to static overvoltage conditions. In such cases, the ESD protection circuit within an IC may redirect the current generated due to static overvoltage conditions to ground. In other cases, an ESD protection circuit may respond to transient voltage/current events. In such cases, a fast-changing voltage or current causes the ESD protection circuit to rapidly turn on.

Some ESD protection circuits include a diode, a metal-oxide-semiconductor-field-effect-transistor (MOSFET), or a silicon-controlled rectifier (SCR). ESD protection circuits often are used on I/O ports at higher voltage (e.g., 65V) or between power rails, to release electrostatic stress before the electrostatic stress damages interior or core electronic circuits in an IC. In some high voltage applications, the ESD protection circuit includes a drain-extended metal-oxide-semiconductor-field-effect (DEMOS) transistor or a laterally diffused metal-oxide-semiconductor (LDMOS) transistor.

The use of LDMOS/DEMOS transistors, however, may be undesirable because the maximum current that may flow through the drain of an LDMOS/DEMOS transistor is limited. In general, the upper limit on the drain current through an LDMOS/DEMOS transistor is the saturation current for a given gate-to-source voltage. The current flowing through the drain of an LDMOS/DEMOS transistor is limited by the carrier concentration of the drain extension region of such transistors. Because increasing the carrier concentration in the drain extension increases the drain current, in some cases the aforementioned limitation may be alleviated by increasing the doping concentration of the drain extension region. Unfortunately, increasing the doping concentration in the drain extension region decreases the breakdown voltage of an LDMOS/DEMOS transistor, which may render it unsuitable for the target ESD application.

In some cases, an insulated-gate bipolar transistor (IGBT) may be used instead of an LDMOS/DEMOS transistor for ESD applications. An IGBT is similar in structure to LDMOS/DEMOS and may overcome the problem of drain current saturation at high gate-to-source voltages by introducing an additional diffusion layer. The additional diffusion layer injects minority carriers into the drain extension region. The injected minority carriers increase the carrier concentration in the drain extension region, which further increases the drain current.

However, introducing an additional diffusion layer causes additional challenges, such as the formation of a parasitic silicon-controlled rectifier (SCR). Assuming an n-type DEMOS/LDMOS transistor, the parasitic SCR is formed due to the introduction of a parasitic PNP bipolar junction transistor (BJT) that couples to an intrinsic parasitic NPN BJT. The parasitic SCR may form a low impedance path between the power supply rails (between which the ESD protection circuit is connected) at a voltage lower than the rated voltage of the power supply rails causing the parasitic SCR structure to shunt current (i.e., latch-up) even in cases where there is no ESD event. As a result, the safe operating area (SOA) of the IGBT is degraded. Latching-up, due to the presence of this parasitic SCR, may disrupt the normal functioning of the circuit to which the ESD protection circuit is coupled. The examples disclosed herein describe an electronic device that addresses the latch-up problem caused by the parasitic SCR.

Accordingly, at least some of the examples disclosed herein are directed towards an electronic device, e.g., an IGBT, usable in, for example, an ESD protection circuit that reduces the likelihood of, or prevents, the occurrence of a latch-up condition. In some examples, the latch-up condition is prevented by constructing an IGBT in such a way that results in a voltage drop between a source region of the IGBT and a silicide. The source region of the IGBT has a doping concentration with a range that causes a Schottky barrier to form between the source region and the silicide. As will be described below, the rectifying barrier created by the Schottky barrier reverse biases a P-N junction of a parasitic BJT within the IGBT. The reverse biased P-N junction helps to avoid a low impedance current path from otherwise forming within a parasitic SCR of the IGBT. Further, the body region of the IGBT abuts the source region. The source and body regions share a common electrode. As a result of the lack of a separate body electrode (apart from a source electrode) and the body region abutting the source region (which means that no isolation material is present between the source and body regions), the IGBT described herein is smaller, all else being equal, to an IGBT that has a body electrode.

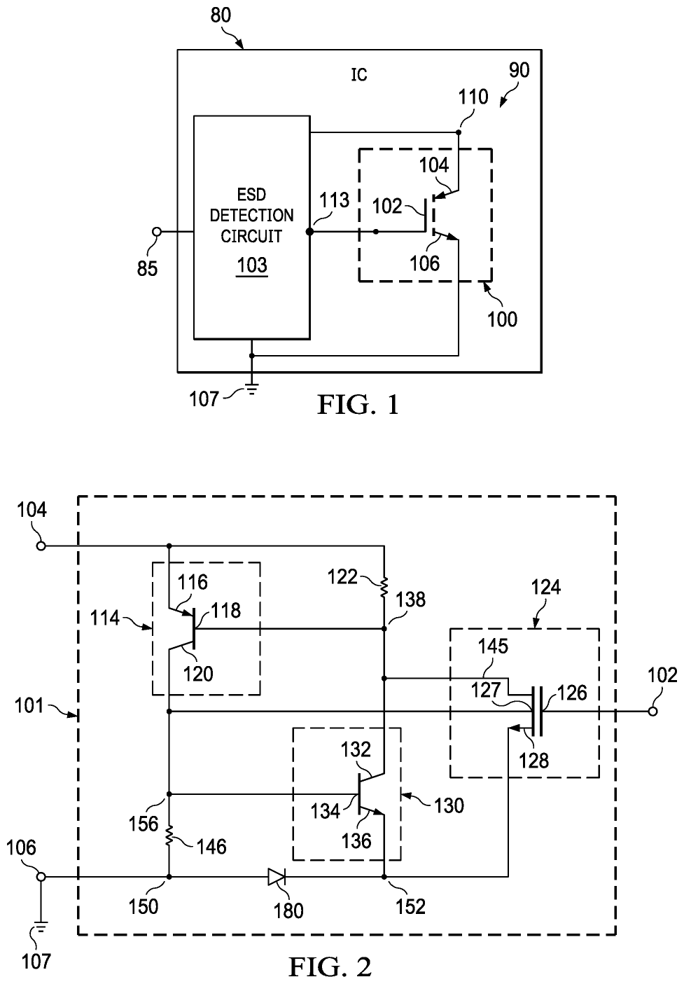

FIG. 1 depicts an integrated circuit (IC) 80 containing an illustrative ESD protection circuit 90 that includes an ESD detection circuit 103 coupled to an electronic device 100 and to a terminal 85 of the IC 80. The device 100 couples to the terminal 85 through the ESD detection circuit 103. The terminal 85 may comprise an externally-accessible pin of the IC 80 or may be coupled to an externally-accessible pin of the IC. The terminal 85 is the terminal that may experience an elevated voltage due to an ESD event. The ESD protection circuit 90 protects other components (not shown) within the IC 80 from a large current due to an ESD event on the terminal 85. In some implementations, a separate ESD protection circuit 90 may be coupled to, and used to protect, each terminal 85 benefitting from ESD protection.

The device 100 includes a gate terminal 102, a collector terminal 104, and an emitter terminal 106. The collector terminal 104 connects to an anode of the device 100. For reasons which will be described below, emitter terminal 106 may also be referred to as a source terminal 106. The source terminal 106 is connected to ground as is the ESD detection circuit 103. The gate terminal 102 is coupled to a gate output terminal 113 of the ESD detection circuit 103. Responsive to an ESD event detected by the ESD detection circuit 103, the ESD detection circuit generates a gate drive signal through its gate output terminal 113 to the gate terminal 102 of device 100 to thereby turn on the device 100 and provide a current path through the device 100 between the terminal 85 and ground. The collector terminal 104 is coupled to a terminal 110 of the ESD detection circuit 103. The ESD detection circuit 103 provides an anode signal (e.g., ESD current) from its terminal 110 to the collector terminal 104 of device 100.

As can be seen in FIG. 1, the source terminal 106 of the device 100 is connected to ground. In some cases, such as that described in U.S. Pat. No. 10,249,610, (the “'610 patent”), incorporated herein by reference in its entirety, a reverse bias device is connected between an IGBT source terminal and ground. This reverse bias device is usable to avoid a low impedance current path that may otherwise form through the IGBT's parasitic SCR. The device 100 described in this present disclosure, however, eliminates the reverse bias device by forming a rectifying barrier within the device 100 that results in a similar electrical behavior as the circuit described in the '610 patent.

During operation, an ESD event may cause a high voltage transient to occur at the terminal 85, which may result in the flow of relatively high current (e.g., 1.5 A) for a few microseconds. The ESD detection circuit 103 senses such an event and, in response, generates a gate signal at its gate output terminal 113 to thereby turn on the device 100. The construction of device 100 is such that a Schottky barrier is formed between a source of a MOSFET within IGBT and a silicide layer. The potential difference between the MOSFET's source and the silicide layer introduces a voltage drop between the MOSFET's source and ground 107. As such, the gate signal from the ESD detection circuit 103 to the gate terminal 102 of the device 100 may need to be higher than the gate signal otherwise needed to turn on the device 100 absent the voltage drop introduced by the Schottky barrier. Stated another way, for the device 100 to turn on, the presence of the voltage drop caused by the Schottky barrier results in a higher voltage with respect to ground being needed on the gate terminal 102. The higher voltage needed to turn on device 100 may be substantially equal to the voltage drop across the Schottky barrier. Advantageously, the presence of the Schottky barrier also reverse biases the base-to-emitter P-N junction of a parasitic N-P-N BJT within the device thereby precluding a low impedance current path from activating within a parasitic SCR of the device. The device 100 disclosed herein is an n-channel IGBT and the principles described are applicable as well to a p-channel IGBT.

FIG. 2 depicts an illustrative equivalent circuit diagram 101 of the device 100. The equivalent circuit diagram 101 includes a P-N-P BJT 114, an N-P-N BJT 130, and a MOSFET 124. For simplicity, the P-N-P BJT 114 and the N-P-N BJT 130 may be referred to as the BJT 114 and the BJT 130, respectively. The BJTs 114 and 130 are parasitic transistors. The BJT 114 includes an emitter 116, a collector 120 and a base 118. The emitter 116 of the BJT 114 forms the collector terminal 104 of the device 100 and couples to the terminal 110 of the ESD detection circuit 103. The BJT 130 includes a collector 132, a base 134, and an emitter 136. The MOSFET 124 includes a gate 126, a drain 145, a body 127, and a source 128. The source 128 of the MOSFET 124 is coupled to the emitter 136 of the BJT 130 and couples to the source terminal 106 via a diode 180 that has a cathode connected to the emitter 136 and the source 128 at a node 152. Diode 180 represents the voltage drop caused by the Schottky barrier that is formed within device 100 that may be operated in a Zener diode configuration (e.g., in reverse breakdown). Because the source 128 is coupled to the emitter 136, source terminal 106 can be referred to as either the IGBT's emitter terminal or the IGBT's source terminal.

A resistor 122 is a representation of the resistance characterized by the carriers in the device 100 and thus may not be a physical resistor coupled between the emitter 116 and the drain 145. Similarly, a resistor 146 that connects to the cathode of the diode 180 at a node 150 also models a parasitic resistance. The collector 132 couples to the base 118 at the node 138. The collector 120 couples to the base 134 at a node 156. The collector 132 couples to the collector terminal 104 through the resistor 122. The gate 126 couples to the gate output terminal 113 of the ESD detection circuit 103.

The MOSFET 124 also includes a drain 145 that couples to the base 118 of the BJT 114 at the node 138. The body 127 of the MOSFET 124 is coupled to the collector 120. As described herein, a voltage is created by a Schottky barrier (modeled by diode 180 in FIG. 2. The voltage drop created by the Schottky barrier in reverse breakdown means that a higher voltage is needed on the gate 126 with respect to ground 107 in order for the Vgs of the MOSFET 124 to be high enough (e.g., greater than the threshold voltage of the MOSFET 124) to thereby turn on the MOSFET.

Because the P-type emitter of P-N-P BJT 114 is coupled to the P-type base of N-P-N BJT 130, a series connection of P-N-P-N junctions is formed by the BJTs 114 and 130. One P-N junction is formed between the P-type emitter 116 and the N-type base 118. An N-P junction is formed between the N-type base 118 and the P-type collector 120. Finally, a P-N junction is formed between the P-type base 134 and the N-type emitter 136. This series connected set of P-N-P-N junctions forms a parasitic SCR which, absent the Schottky barrier described herein, may otherwise result in the formation of a low impedance current path to ground even with no large voltage transient during an ESD event (and the device 100 not being on). The voltage resulting from the Schottky barrier (e.g., the diode 180) causes the N-type emitter 136 of N-P-N BJT 130 to have a higher voltage than the P-type base 134. As such, the P-N junction formed between P-type base 134 and N-type emitter 136 is reversed biased. By reverse biasing the base-to-emitter P-N junction of BJT 130, the formation of a low impedance path that might otherwise have been created by a parasitic SCR formed by the combination of BJTs 114 and 130 is avoided.

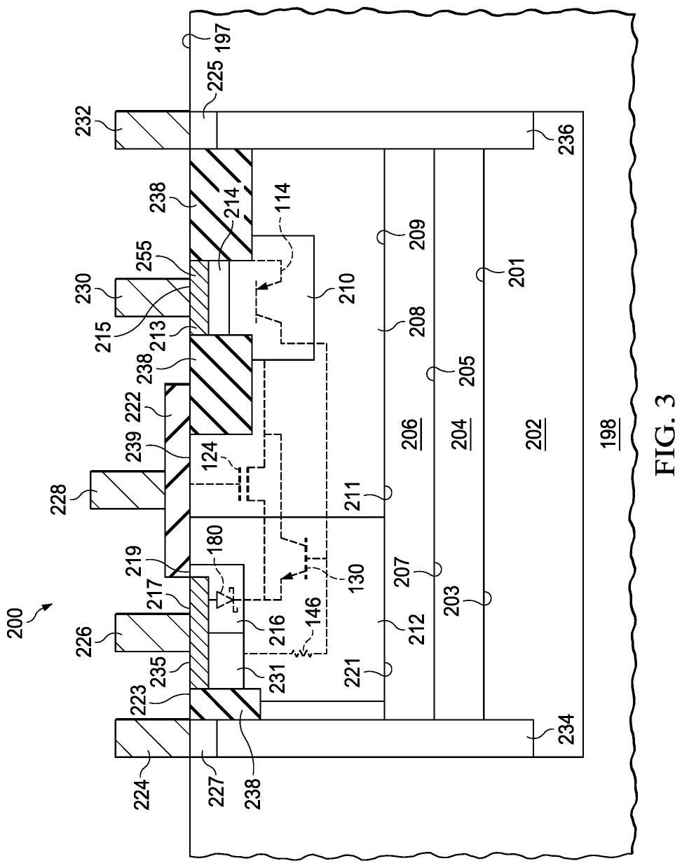

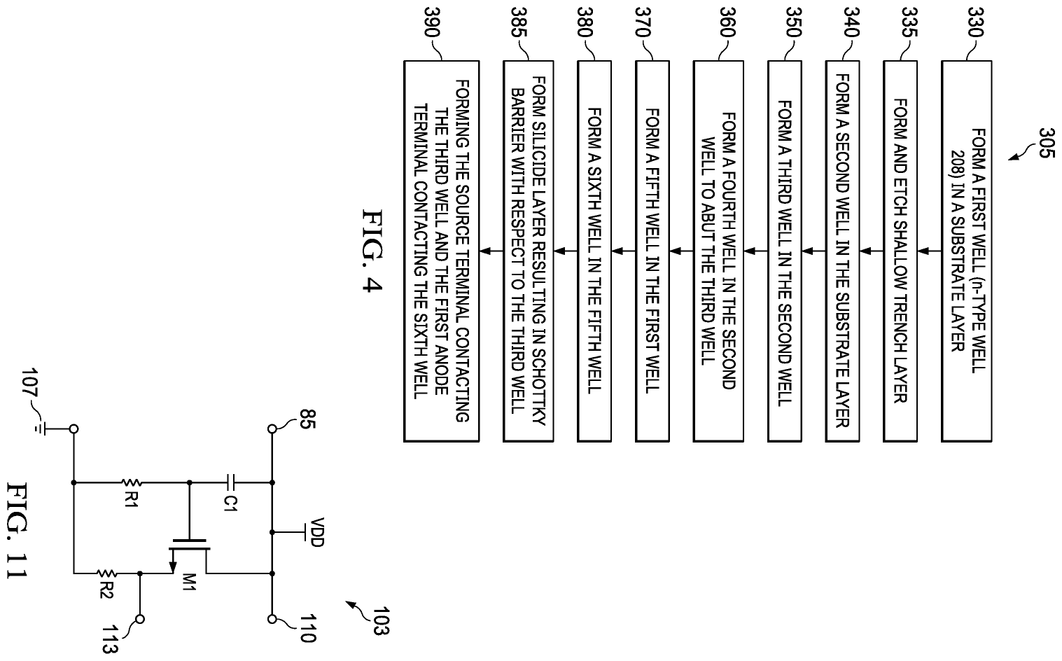

FIG. 3 depicts a side-view cross section of at least a portion of device 100, designated device 200 for the purpose of discussion. The device 200 includes a substrate 198 that may be formed using silicon. The substrate 198 may be doped with P-type dopants (e.g., group III elements of the periodic table). The device 200 also includes N-type buried layer 202 having a top surface 201. The N-type buried layer 202 may be formed by implanting N-type dopants (e.g., group V elements of the periodic table) in the substrate 198. The device 200 includes a P-type epitaxial layer 204 formed by growing P-type silicon on the substrate 198. The P-type epitaxial layer 204 includes a top surface 205 and a bottom surface 203. The bottom surface 203 of the P-type epitaxial layer 204 interfaces with the top surface 201 of the N-type buried layer 202. The term “substrate” may refer to the substrate 198 with the p-type epitaxial layer 204.

In the example of FIG. 3, the device 200 further includes a P-type buried layer 206 including a top surface 209 and a bottom surface 207. In other examples, the p-type buried layer 206 is not included. The bottom surface 207 of the P-type buried layer 206 interfaces with the top surface 205 of the p-type epitaxial layer 204. The P-type buried layer 206 is formed by implanting P-type dopants in the P-type epitaxial layer 204.

The device 100 includes an N-type well 208 that is sometimes referred to as a deep N-well, DNWELL, or deep well. The DNWELL 208 is formed by implanting N-type dopants in the P-type substrate 198. The DNWELL 208 includes a top surface 239 and a bottom surface 211. The bottom surface 211 interfaces with the top surface 209 of the P-type buried layer 206. The top surface 239 of the DNWELL 208 is coincident with a top surface 197 of the substrate 198.

The device 200 includes a P-type well 212 formed by implanting P-type dopants in the DNWELL 208 and includes a top surface 219 and a bottom surface 221. The P-type well 212 may be referred to as a double-diffused well, or DWELL, and may operate as a body region of the device 200. In the example shown, the bottom surface 221 of the P-type DWELL 212 interfaces with the top surface 209 of the DNWELL 208. The top surface 219 of the P-type DWELL 212 is coincident with the top surface 197 of the substrate 198. The DWELL 212 forms a junction with the DNWELL 208 that intersects the top surface of the substrate 198.

The device 200 further includes an N-type shallow source 216 that is formed by adding N-type dopants to the P-type DWELL 212. In one example, the dopant used for the N-type shallow source 216 (and thus the source 128 of the MOSFET 14) is arsenic and has a dopant concentration in the range of 10¹⁸ atoms/cm³ to 10²⁰ atoms/cm³. The N-type shallow source 216 includes a top surface 217 that is coincident with the top surface 197 of the substrate 198. The N-type shallow source 216 forms the source 128 of the MOSFET 124 (FIG. 2). An electrode 226 is formed over the N-type shallow source 216 and represents the source terminal 106 of the device.

The device 200 also includes a P-type body tap 231 that is formed by adding additional P-type dopants (e.g., boron) to the P-type DWELL 212. The P-type body tap 231 includes a top surface 223 that is coincident with the top surface 197 of the substrate 198. The P-type body tap 231 represents the body 127 of the MOSFET 124. As can be seen, a side surface of the P-type body tap 231 abuts a side surface of the N-type shallow source 216. In some examples, a dielectric isolation structure is located between the body tap 231 and the shallow source 216. Further, the example of FIG. 3 shows a single electrode 226 that is shared between the P-type body tap 231 and the N-type shallow source 216. The electrode 226 is represented by the source terminal 106 in FIG. 2.

A silicide layer 235 (or other type of metallic structure) is formed between the electrode 226 and N-type shallow source 216 and is over at least a portion of a surface of the N-type shallow source 216 and at least a portion of the body tap 231. The metal silicide may be formed by a reaction between silicon of the shallow source 216 and a refractory method such as tungsten, titanium or platinum. The dopant concentration of the N-type shallow source 216 is low enough that a Schottky barrier forms between the N-type shallow source 216 and the silicide layer 235. The significance of this Schottky barrier is discussed. Due to the type and concentration level of the doping in P-type body tap 231 (e.g., having a higher carrier concentration than for the N-type shallow source 216), the electrode 226 is in ohmic contact with the body tap 231 and in rectifying contact (via the Schottky barrier) with the N-type shallow source 216). FIG. 3 also shows silicide 255 between an electrode 230 and a P-type drain region 214. Silicide (not shown) also may be formed at the junction between the other electrodes shown in FIG. 3 and the underlying silicon.

The device 200 in this example includes an N-type well 210, sometimes referred to as NWELL 210, that is formed by implanting N-type dopants in the DNWELL 208. The N-type well 210 includes a top surface 215 that is coincident with the top surface 197 of the substrate 198. The N-type well 210 represents the drain of the MOSFET 124.

P-type drain region 214 is formed by implanting P-type dopants, e.g., boron, in the DNWELL 208, and may have a dopant concentration in a range of approximately 10¹⁹ atoms/cm³-10²⁹ atoms/cm³. Typically the dopant concentration in the drain region 214 is greater than the dopant concentration in the shallow well 216. The P-type drain region 214 includes a top surface 213 coincident with the top surface 197 of the substrate 198. The electrode 230 is formed over the P-type drain region 214 and represents the collector terminal 104 of the device 200.

The device 200 includes wells 234 and 236 that are doped with N-type dopants and extend from the top surface 197 of the substrate 198 into the N-type buried layer 202. Electrodes 224 and 232 are formed over wells 234 and 235, respectively, and may be used to bias the buried layer 202 for isolation purposes. The device 200 also includes a gate oxide layer 222 over which is formed a gate electrode 225 that represents the gate 126 of the MOSFET 124. An electrode 228 provides an electrical connection to the gate electrode 225.

In the example of FIG. 3, the device 200 also includes shallow trench isolation (STI) structures 238 that isolate active regions in the DNWELL 208. As can be seen, the P-type body tap 231 and the N-type shallow source 216 abut one another and thus there is no shallow trench isolation layer portion therebetween. This configuration is possible due to the low dopant concentration of the shallow source 216, whereas in a conventional IGBT it is typically necessary to isolate the source from the body tap. While the illustrated abutment of the shallow source 216 and the body tap 216 makes possible a smaller area of the device 200, in other examples, an isolation structure is placed between these regions.

As explained above, the device 200 includes parasitic BJTs 114 and 130 in addition to the MOSFET 124. These three deices are shown in schematic form in FIG. 3 without implied limitation. The BJT 114 forms between the P-type drain region 214, P-type DWELL 212, DNWELL 208, and N-type well 210. The emitter 116 of the BJT 114 is formed by the P-type drain region 214. DNWELL 208 and the N-type well 210 may function as the base 118, and the P-type DWELL 212 may function as the collector 120. The emitter 116 is coupled to the electrode 230 (also representing the collector terminal 104).

The BJT 130 forms between the N-type shallow source 216, the P-type DWELL 212, the DNWELL 208, and N-type well 210. The N-type shallow source 216 may operate as the emitter 136, and the N-type wells 208 and 210 may operate as the collector 132. The emitter 136 of BJT 130 is coupled to the electrode 226 via the Schottky diode 180. The electrode 226 provides connectivity to the source terminal 106 of the device 200. The MOSFET 124 includes the N-type shallow source 216, N-type wells 208 and 210 and the gate electrode 225, with the electrode 228 operating as the gate terminal 102.

Whereas in a conventional IGBT the drain region 214 and a source region at the location of the shallow source 216 typically receive a dopant during a same source/drain (S/D) implant, for the device 200 the drain region 214 may receive a dopant during the S/D implant, while the shallow source 216 only receives an n-type dopant by an implantation step the uses the DWELL pattern. Thus, the source and drain of a conventional IGBT may have same or similar dopant concentrations, while for the device 200 the dopant concentrations of the shallow source 216 and the drain region 214 are not constrained to be similar. Thus, the doping level of the shallow source 216 may be tailored to produce the Schottky barrier previously described, when may be used to effectively embed a diode in the structure of the device 200.

The '610 patent describes an IGBT having an equivalent circuit similar to FIG. 2 with a reverse bias device that may be implemented by an external diode. The inventors have recognized that the function of such a diode may be effectively implemented by the embedded Schottky barrier between the shallow source 216 and the DWELL 212. Without limitation by theory, it is believed that the Schottky barrier may be understood to operate as or similar to a Schottky diode with its anode connected to the source terminal 106 and its cathode connected to the node 152 (FIG. 2). The Schottky barrier is represented by the Schottky diode 180 in FIG. 2, and is oriented in FIG. 3 such that the anode is coincident with the silicide layer 235 and the cathode is coincident with the shallow source 216. The Schottky diode 180 has a turn-on voltage drop when forward biased by at least the turn-on voltage, and a breakdown voltage drop when reverse biased by at least the breakdown voltage. While the diode implemented in the '610 patent is connected such that its anode is connected to the node 152 and its cathode is connected to the source terminal 106, the Schottky barrier of the present disclosure was unexpectedly determined to have similar functionality even though the anode and cathode of the Schottky diode are oriented oppositely to the diode of the '610 patent. By integrating the Schottky diode in the device 200, the component count of a circuit utilizing the device 200 is reduced, the die size of the device 200 may be reduced, and reliability is expected to improve by reducing external connections.

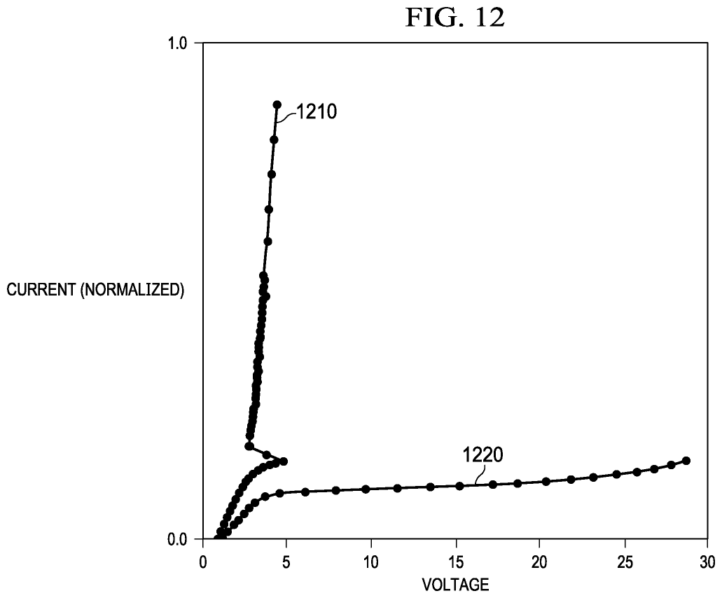

The effectiveness of the integration of the Schottky diode 180 in the device 200 is illustrated by FIG. 12, in which current and voltage for transmission line pulse (TLP) characterization are shown for an IGBT having a conventional source dopant concentration, and an electronic device consistent with the principles described herein in which the source dopant concentration is reduced thus forming a Schottky barrier between the source and an overlying silicide layer. A safe operating area (SOA) is determined from each curve, related to a snapback voltage of the device. I-V characteristic 1210 describes the operation of the conventional IGBT, and evidences snapback at 5 V, indicating an SOA of 5 V. I-V characteristic 1220 describes the operation of the device including the integrated Schottky barrier, and evidences no snapback up to 28 V, indicating an SOA of at least 28 volts. A typical device specification may require a minimum snapback voltage of 20 V. The conventional IGBT is noncompliant with this specification, while the device including the integrated Schottky barrier is compliant, demonstrating the functionality and benefit of the described examples.

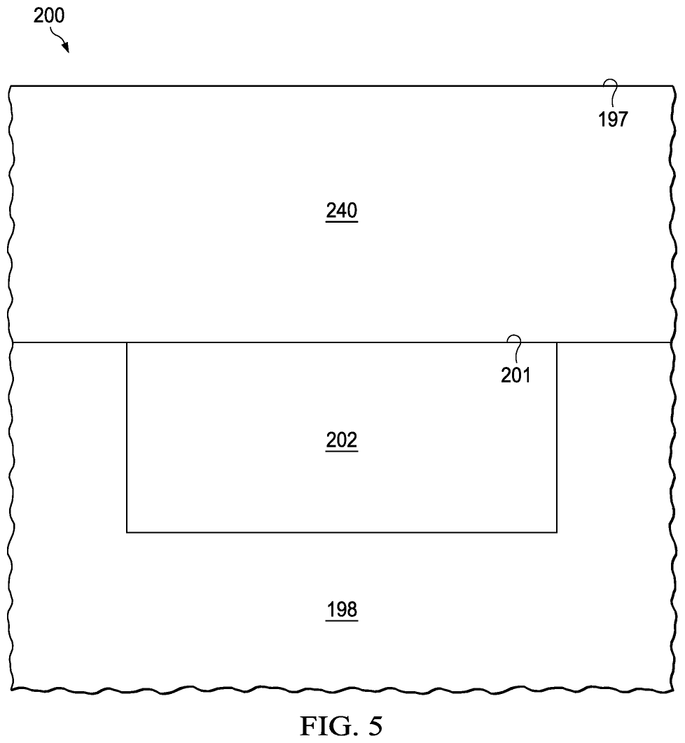

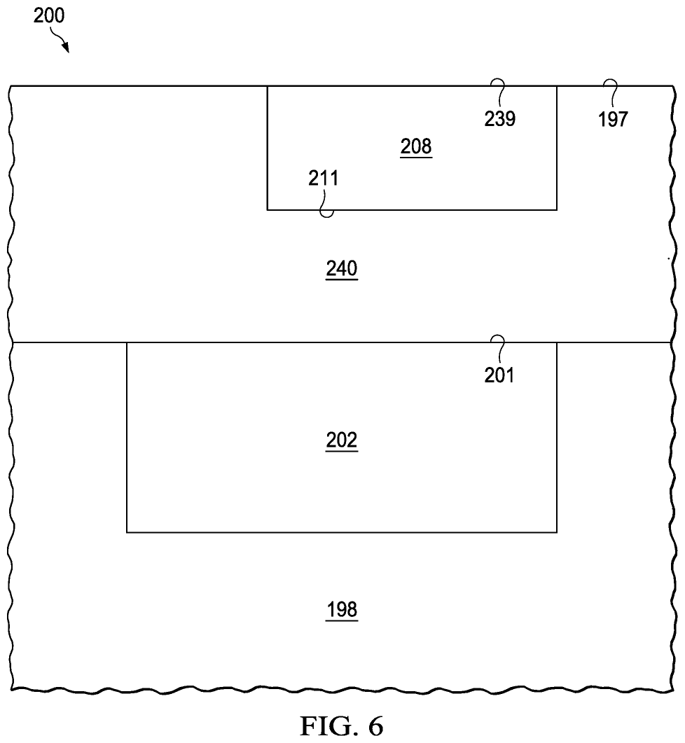

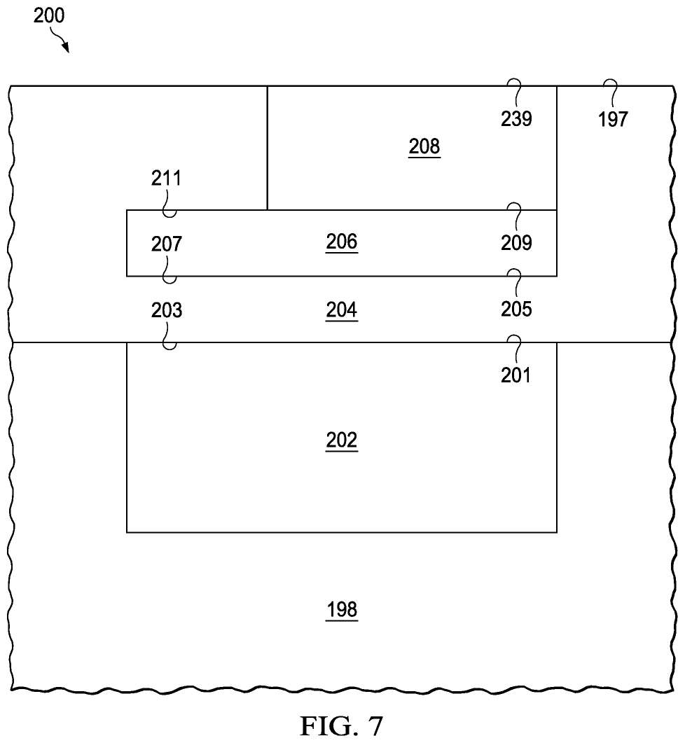

FIG. 4 depicts an example of a method 305 to fabricate the device 200. The method 305 is now described in tandem with FIGS. 5-10. At step 330, method 305 includes forming a first well (e.g., DNWELL 208) in substrate 198. In at least some process flows, prior to forming the first well in the substrate 198 (which is doped at a concentration of around 10¹⁵ atoms/cm³10¹⁶ atoms/cm³), the substrate 198 may go through one or more fabrication steps, such as implanting N-type dopants in the substrate 198 to form the N-type buried layer 202 (doped at concentration of around 10¹⁸ atoms/cm³-10¹⁹ atoms/cm³). The N-type buried layer 202 has a top surface 201 (FIG. 5). Following the formation of the N-type buried layer 202, a P-type epitaxial layer 240 is grown on the substrate and doped at, for example, a concentration of approximately 10¹⁵ atoms/cm³. Further, the DNWELL 208 (doped at concentration of around 10¹⁶ atoms/cm³-10¹⁷ atoms/cm³) may be formed by implanting N-type dopants in the substrate 198 (FIG. 6). The DNWELL 208 includes the top surface 239 and the bottom surface 211. In some examples, the substrate 198 may further be implanted with P-type dopants to form the P-type buried layer 206 (doped at concentration of around 10¹⁶ atoms/cm³-10¹⁷ atoms/cm³) including top and bottom surfaces 209 and 207, respectively. Following the formation of the P-type buried layer 206, the epitaxial layer 240 may be represented as the P-type epitaxial layer 204 with top and bottom surfaces 205 and 203 as shown in FIG. 7.

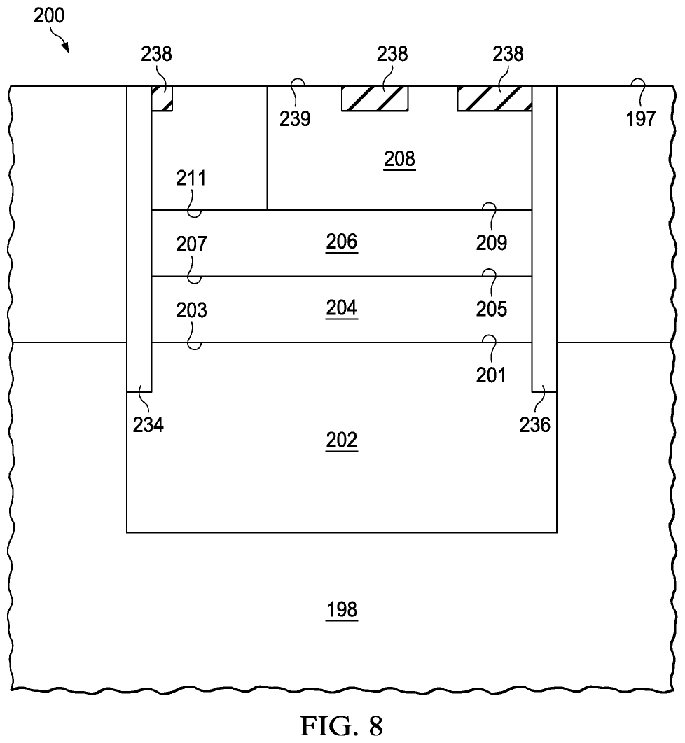

At step 335, method 305 includes forming and etching the STI structure 238 (or LOCOS) thereby resulting in multiple shallow trench isolation portions as illustrated in FIG. 8. The STI structure 238 includes portions that isolate active regions in the DNWELL 208.

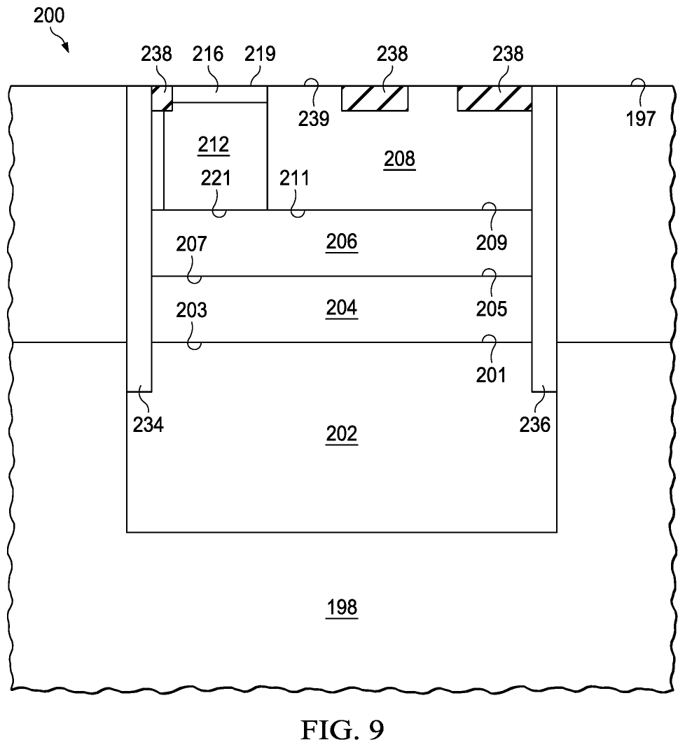

The method 305 proceeds with step 340, which includes forming a second well (e.g., the P-type DWELL 212) in the substrate 198 as shown in FIG. 9. This step may include implanting a P-type dopant as such As in the substrate 198 to form the P-type DWELL 212. The dopant concentration may be in the range of approximately 10¹⁸ atoms/cm³-10¹⁹ atoms/cm³. The P-type DWELL 212 includes the top and bottom surfaces 219 and 221. The implanting converts a portion of the DWELL 212 to N-type, producing a third well, e.g. the shallow source 216.

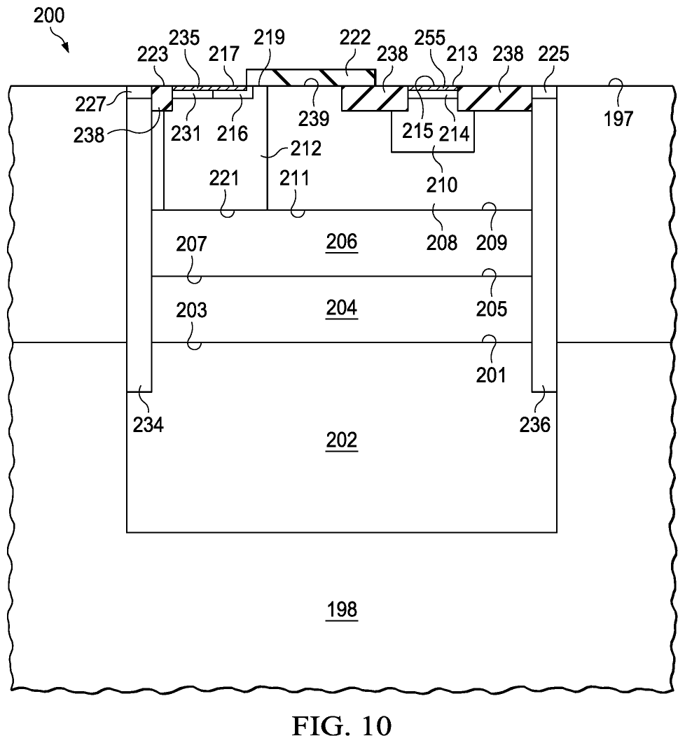

In some examples, the gate oxide layer 222 may be formed over the top surface 197 prior to proceeding with the step 350. At step 350, the method 305 includes forming a third well (e.g., the shallow source 216) in the second well (e.g., the p-type DWELL 212) as shown in FIG. 10. This step may include implanting an N-type dopant in the p-type well 212 to form the N-type shallow source 216. The dopant, which may be arsenic in one example, may have a concentration in the range of approximately 10/¹⁸ atoms/cm³-10²⁹ atoms/cm³. As described further below, the dopant concentration of the shallow source 216 is low enough to ensure a Schottky barrier is formed between the shallow source 216 and an overlying silicide layer that is later formed on the shallow source.

The method 305 then proceeds with step 360 which includes forming a fourth well (P-type body tap 231) in the second well (P-type DWELL 212). In the illustrated example, the formation of the fourth well (P-type body tap 231) results in the fourth well abutting the third well (n-type shallow source 216) as shown in FIG. 10, though in other examples a dielectric isolation structure may separate the shallow source 216 from the body tap 231. Step 360 may include implanting a P-type dopant such as boron in the P-type DWELL 212 to form the P-type body tap 231.

The method 305 further proceeds to step 370, which includes forming a fifth well (e.g., the N-type well 210) in the first well (e.g., the DNWELL 208). This step may be performed by implanting an N-type dopant in the DNWELL 208 to form the N-type well 210 at a dopant concentration in the range of approximately 10¹⁷ atoms/cm³-10¹⁸ atoms/cm³). The N-type well 210 is shown in FIG. 10.

The method 305 further moves to step 380 which includes forming a sixth well (e.g., the P-type drain region 214) in the fifth well (e.g., the N-type well 210). This step may be performed by implanting P-type dopants (dopant concentration in the range of approximately 10¹⁹ atoms/cm³-10²⁹ atoms/cm³) in the N-type well 210 to form the P-type well 214.

At step 385, a silicide layer (e.g., the silicide layer 235) is formed on the substrate 198 (shown in FIG. 10). As explained above, the combination of the N-type shallow source 216 and the silicide layer 235 forms a Schottky barrier which results in a voltage drop developing between the N-type shallow source 216 and the silicide layer 235). The voltage resulting from the Schottky barrier is expected to reverse-bias the P-N junction of the P-type base 134 of BJT 130 and the N-type emitter 136 of the BJT 130 and thus prevents the formation of a low impedance current path through the parasitic SCR of BJTs 114 and 130.

At step 390, the method 305 includes forming the electrodes 226, 228, and 230 for the device's source, gate, and anode, respectively, as are shown in FIG. 3. The electrode 228 electrically connects to the gate electrode 225 via an unreferenced silicide layer. The electrode 230 connects to the P-type drain region 214 for the anode via silicide 255, and the electrode 226 connects via the silicide layer 235 to the N-type shallow source 216 for the source and the P-type body tap 231.

The Schottky barrier described above forms between the silicide layer 235 and the N-type shallow source 216. However, in some cases the device 200 does not include the silicide layer 235 between the electrodes (e.g., electrodes 226 and 230) and the corresponding wells (e.g., drain region 214, shallow source 216, and body tap 231). In such transistors, the electrode 226 directly touches the N-type shallow source 216 and the P-type body tap 231, and due to the doping concentration of the N-type shallow source 216, a Schottky barrier is formed between the electrode 226 and the N-type shallow source 216. In some examples, the N-type shallow source 216 in this configuration may be doped as described above (e.g., arsenic with a dopant concentration in the range of 10¹⁸ atoms/cm³ to 10²⁰ atoms/cm³).

FIG. 11 shows an example implementation of the ESD detection circuit 103. In this example, the ESD detection circuit 103 includes a capacitor C1, resistors R1 and R2, and a transistor M1. Terminal 85 is coupled to capacitor C1. Capacitor C1 is coupled to resistor R1 and to the gate of transistor M1 (which is an N-type metal oxide semiconductor field effect transistor in this example). The gate output terminal 113 is provided by the connection between the drain of M1 and resistor R2. Terminal 85 is connected to the power supply rail (VDD).

The ESD detection circuit 103 detects an ESD event during its power-off state (the IC is not powered on and thus VDD is 0 V). During the power-off state and absent an ESD event, terminal 85 is at the ground potential due to VDD being off, and the gate of the transistor M1 is pulled to ground via resistor R1. With the gate of M1 being ground, M1 is off and no current flows through R2 thereby pulling the gate output terminal 113 to ground. During an ESD event, a fast voltage transient appears at the terminal 85. This voltage transient on the terminal 85 is coupled through the capacitor C1 to the gate of M1 to thereby briefly turning on M1 (M1 is turned on while the transient persists). With M1 being, the source of M1 and thus the gate output terminal 113 is pulled up to nearly the voltage of the voltage transient on terminal. The elevated voltage on the gate output terminal 113 triggers the IGBT as explained above.

The ESD detection circuit 103 of FIG. 11 is an example of voltage transient circuit (sometimes referred as a “DV/DT” circuit. In other examples, the ESD detection circuit 103 comprises a voltage level detection circuit which increases the voltage on the gate output terminal 113 in response to the voltage on the terminal 85 exceeding a threshold level.

The term “couple” is used throughout the specification. The term may cover connections, communications, or signal paths that enable a functional relationship consistent with the description of the present disclosure. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A.

Modifications are possible in the described embodiments, and other embodiments are possible, within the scope of the claims.

What is claimed is:

1. An electronic device, comprising:
a first well having a first conductivity type within a semiconductor substrate;
a second well having a second opposite conductivity type within the semiconductor substrate and touching the first well;
a third well having the first conductivity type within the second well; and
a metallic structure in direct contact with at least a portion of a surface of the third well thereby forming a Schottky barrier between the third well and the metallic structure.

2. The electronic device of claim 1, wherein the third well is an N-type well.

3. The electronic device of claim 1, wherein a concentration of a dopant of the third well is in the range of 10¹⁸ to 10²⁰ atoms per cubic centimeter.

4. The electronic device of claim 3, wherein the dopant of the third well includes arsenic.

5. The electronic device of claim 1, further comprising a fourth well within the first well, wherein the fourth well provides an emitter of a parasitic bipolar junction transistor (BJT), the second well provides a base of the parasitic BJT, and the third well provides a collector of the parasitic BJT; and
the Schottky barrier is configured to bias the -emitter of the parasitic BJT during operation.

6. The electronic device of claim 1, further including a fourth well, the fourth well being a body tap of the electronic device, the third well being the source of the IGBT, and the third and fourth wells abut one another.

7. The electronic device of claim 6, wherein a doping concentration of the fourth well is higher than the doping concentration of the third well.

8. The electronic device of claim 6, further including an electrode shared between the source and the body tap.

9. An integrated circuit (IC), comprising:
an ESD detection circuit having an input terminal and an output terminal; and
insulated-gate bipolar transistor (IGBT) coupled to the output terminal of the ESD detection circuit, the IGBT having a first deep well of a first conductivity type within a substrate, a deep well (DWELL) of a second different conductivity type within the substrate and forming a junction within the first well, a shallow source having the first conductivity type within the DWELL, and a silicide layer over at least a portion of a surface of the shallow source thereby forming a Schottky barrier between the shallow source and the silicide layer.

10. The IC of claim 9, wherein the shallow source is an N-type well doped with arsenic at a concentration in the range of 10¹⁸ to 10²⁰ atoms per cubic centimeter.

11. The IC of claim 9, wherein:
the IGBT includes a parasitic bipolar junction transistor having a base provided by the DWELL and an emitter provided by the shallow source; and
the Schottky barrier is configured to reverse bias the base-to-emitter junction of the parasitic bipolar junction transistor.

12. The IC of claim 9, further including a fourth well, the fourth well that provides a body tap of the IGBT, the shallow source abutting the fourth well.

13. The IC of claim 12, wherein the silicide layer conductively connects the shallow source and the body tap.

14. The IC of claim 9, further comprising a drain region having the second conductivity type extending between a surface of the substrate and the first well, wherein the drain region has a greater dopant concentration than the shallow source.

15. The IC of claim 14, further comprising a gate electrode that covers a portion of the shallow source and extends towards the drain region and over the junction between the first well and the DWELL.

16. The IC of claim 9, wherein a Schottky diode defined by the Schottky barrier has an anode coincident with the silicide layer and a cathode coincident with the shallow source.

17. A method for forming an integrated circuit, comprising
forming a first well region having a first conductivity type within a semiconductor substrate;
forming a second well region having a second conductivity type within the substrate, the second well region forming a junction with the first well region that intersects a top surface of the substrate;
forming a drain region having the second conductivity type extends between the top surface and the first well region;
forming a gate electrode located over the junction;
forming a shallow source region having the first conductivity type within the second well region; and
forming a metal silicide on the shallow source region, the metal silicide forming a Schottky barrier with the shallow source region.

18. The method of claim 17, wherein the gate electrode extends over the shallow source region.

19. The method of claim 17, wherein the gate electrode grain region has a greater dopant concentration than the shallow source region.

20. The method of claim 17, wherein a Schottky diode defined by the Schottky barrier has an anode coincident with the metal silicide and a cathode coincident with the shallow source region.
